(19) United States
(12) Patent Application Publication
(10) Pub. No.: US 2025/0203876 A1
(43) Pub. Date: Jun. 19, 2025

(54) METHOD FOR PREPARING A FERROELECTRIC MULTILAYER DEVICE

(71) Applicant: COMMISSARIAT A L'ENERGIE ATOMIQUE ET AUX ENERGIES ALTERNATIVES, Paris (FR)

(72) Inventors: Amanda Mallmann Tonelli, Grenoble (FR); Messaoud Bedjaoui, Grenoble (FR); Laurent Grenouillet, Grenoble (FR); Vincent Jousseaume, Grenoble (FR)

(73) Assignee: COMMISSARIAT A L'ENERGIE ATOMIQUE ET AUX ENERGIES ALTERNATIVES, Paris (FR)

(21) Appl. No.: 18/980,058

(22) Filed: Dec. 13, 2024

(30) Foreign Application Priority Data
Dec. 15, 2023 (FR) 2314317

(51) Int. Cl. H10B 53/30

(52) U.S. Cl. CPC H10B 53/30

(57) ABSTRACT

The present disclosure relates to a method for preparing a ferroelectric multilayer device, in particular an ultrafine device, comprising an alternation of at least one layer of a first type and at least one layer of a second type.

### CROSS-REFERENCE TO RELATED APPLICATION

This application claims priority from French Application No. 2314317, filed on Dec. 15, 2023, the entire contents of which are incorporated herein in its entirety.

### BACKGROUND

This disclosure relates to a method for preparing a ferroelectric multilayer device, in particular an ultrafine device, comprising an alternation of at least one layer of a first type and at least one layer of a second type.

The ferroelectric memories, although less well known than their non-ferroelectric counterparts, in particular the magnetic memories, are attracting growing interest in the field of memory technology, particularly mass storage peripherals.

These ferroelectric materials, characterized by their ability to retain a remanent electrical polarization, quickly attracted the attention of scientists and engineers because of their unique properties. Their use in memory devices offers significant advantages: they are non-volatile, have short read/write times, use voltages compatible with silicon-based electronics and consume little energy.

In recent years, research into ferroelectric memories has been limited by their scalability and incompatibility with complementary metal-oxide-semiconductor (CMOS) technology. Nevertheless, since the discovery of ferro-electricity in 10 nm-thick HfO₂ films in 2011, the ferroelectric memories have attracted growing interest from researchers and semiconductor manufacturers.

Several factors stabilize the non-centrosymmetric orthorhombic phase, which is thought to be responsible for the ferroelectric behavior of hafnium oxide, such as the thermal budget, the concentration of dopants and the thickness of the film.

Despite the properties mentioned above, HfO₂-based materials present crucial challenges that need to be overcome to meet the requirements of ferroelectric memories. One challenge is to reduce their operating voltage while meeting the thermal budget requirements of the methods referred to as “back-end-of-the-line” (BEOL) methods for preparing microelectronic structures and components, where the maximum permissible temperatures are below 450° C.

However, when the aim is to develop ultra-thin films down to a thickness of less than the standard 10 nm, particularly for compactness reasons, an increase in annealing temperature is currently required to obtain the ferroelectric metastable phase and maintain the application properties, exceeding the permitted limit of the BEOL technology.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

This disclosure relates to examples of a method for preparing a ferroelectric device to be implemented which avoids the aforementioned disadvantages.

One purpose of the disclosure is to provide a method for preparing a ferroelectric device, particularly ultra-thin, while allowing to preserve a thermal budget compatible with the BEOL technology.

Another more specific aim of the disclosure is to provide a preparation method allowing to obtain devices that may be configured to ferroelectric memory applications operating at very low voltages.

Thus, according to a first aspect, the disclosure one or more examples of a method for preparing a ferroelectric multilayer device M with n layers, n being greater than or equal to 2, consisting of or comprising an alternation of at least one layer A and at least one layer B,
the at least one layer A independently consisting of or comprising a compound selected from hafnium oxides (HfO₂), hafnium and zirconium oxides (HZO) enriched with hafnium, hafnium and zirconium oxides (HZO) doped with aluminum, hafnium and zirconium oxides (HZO) doped with lanthanum, hafnium and zirconium oxides (HZO) doped with gadolinium, hafnium and zirconium oxides (HZO) doped with yttrium, hafnium and zirconium oxides (HZO) doped with silicon, and hafnium oxides (HSO) doped with silicon.
the at least one layer B being, independently, constituted by or comprising a compound selected from zirconium oxides (ZrO₂), hafnium oxides (HZO) enriched with zirconium, and perovskites,
the method comprising the following steps:
a step of preparing, on a substrate or a lower metal electrode, a multilayer device M′ with n′ layers, n′ being greater than or equal to 3, with n′>n, comprising an alternation of the layers A and B, the first of the n′ layers, in contact with the lower metal electrode, being a layer A,
a step of depositing an upper metal electrode on the multilayer device M′ obtained at the end of step (i), opposite to the lower metal electrode,
a step of annealing the device obtained at the end of step (ii),
a step of removing the upper metal electrode from the device obtained at the end of step (iii),
a selective etching of the n′-n upper layers, opposite to the lower metal electrode, in particular completely, to obtain the multilayer device M on the lower metal electrode,
optionally, a step of depositing an upper metal electrode on the multilayer device M′ obtained at the end of step (v), opposite to the lower metal electrode.

According to another aspect, the disclosure relates to a method for preparing a ferroelectric multilayer device M with n layers, n being between 2 and 100, preferably between 2 and 25, consisting of or comprising an alternation of at least one layer A and of at least one layer B,
the at least one layer A independently consisting of or comprising a compound selected from hafnium oxides (HfO₂), hafnium and zirconium oxides (HZO) enriched with hafnium, hafnium and zirconium oxides (HZO) doped with aluminum, hafnium and zirconium oxides (HZO) doped with lanthanum, hafnium and zirconium oxides (HZO) doped with gadolinium, hafnium and zirconium oxides (HZO) doped with yttrium, hafnium and zirconium oxides (HZO) doped with silicon, and hafnium oxides (HSO) doped with silicon,
the at least one layer B being, independently, constituted by or comprising a compound selected from zirconium oxides (ZrO₂), hafnium oxides (HZO) enriched with zirconium, and perovskites,
the method comprising the following steps:
a step of preparing, on a substrate or a lower metal electrode, a multilayer device M′ with n′ layers, n′ being between 3 and 101, with n′>n, preferably between 3 and 26, comprising an alternation of the layers A and B, the first of the n′ layers, in contact with the lower metal electrode, being a layer A,
a step of depositing an upper metal electrode on the multilayer device M′ obtained at the end of step (i), opposite to the lower metal electrode,
a step of annealing the device obtained at the end of step (ii),
a step of removing the upper metal electrode from the device obtained at the end of step (iii),
a selective etching of the n′-n upper layers, opposite to the lower metal electrode, in particular completely, to obtain the multilayer device M on the lower metal electrode,
optionally, a step of depositing an upper metal electrode on the multilayer device M′ obtained at the end of step (v), opposite to the lower metal electrode.

According to a particular embodiment, the method comprises the following steps:
a step of preparing, on a substrate or a lower metal electrode, a multilayer device M′ with n′ layers, n′ being between 3 and 101, with n′>n, preferably between 3 and 26, comprising an alternation of the layers A and B, the first of the n′ layers, in contact with the lower metal electrode, being a layer A,
a step of depositing an upper metal electrode on the multilayer device M′ obtained at the end of step (i), opposite to the lower metal electrode,
a step of annealing the device obtained at the end of step (ii),
a step of removing the upper metal electrode from the device obtained at the end of step (iii),
a selective etching of the n′-n upper layers, opposite to the lower metal electrode, in particular completely, to obtain the multilayer device M on the lower metal electrode,
a step of depositing an upper metal electrode on the multilayer device M′ obtained at the end of step (v), opposite to the lower metal electrode.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 illustrates a device obtained using a method according to the disclosure as described in example 1, step 1.

FIG. 2 illustrates a device obtained using a method according to the disclosure as described in example 1, step 2.

FIG. 3 illustrates a device obtained using a method according to the disclosure as described in example 1, step 3.

### DETAILED DESCRIPTION

“Hafnium and zirconium oxides (HZO) enriched with zirconium” refers in particular to hafnium and zirconium oxides comprising more than 50% at (atomic concentration) of ZrO₂.

Examples of perovskites include lead zirconate (PbZrO₃) and lead hafniate (PbHfO₃).

Examples of perovskites include lead zirconate (PbZrO₃), lead hafniate (PbHfO₃), PZT/PZO-type perovskites for Pb (Zr, Ti)O₃, barium strontium titanates (BST), and lead-free perovskites (e.g. LNO for LiNbO₃, BFO for BiFeO₃, NBT for Na_{0.5}Bi_{0.5}TiO₃)

The term “hafnium and zirconium oxides (HZO) enriched with hafnium” refers in particular to hafnium and zirconium oxides comprising more than 50% at, preferably about 1% at, of HfO₂.

The term “hafnium and zirconium oxides (HZO) doped with aluminum” refers in particular to hafnium and zirconium oxides comprising from 0.1 to 10% at, preferably about 1% at, of Al₂O₃.

By “hafnium zirconium oxides (HZO) doped with lanthanum” are meant in particular the hafnium and zirconium oxides comprising 0.1 to 10% at, preferably about 1% at, of lanthanum.

By “hafnium zirconium oxides (HZO) doped with gadolinium”, we mean in particular the hafnium and zirconium oxides comprising 0.1 to 10% at, preferably about 1% at, of gadolinium.

By “hafnium zirconium oxides (HZO) doped with yttrium” in particular, we mean hafnium and zirconium oxides comprising 0.1 to 10% at, preferably about 1% at, of yttrium.

By “hafnium and zirconium oxides (HZO) doped with silicon” is meant in particular hafnium and zirconium oxides comprising from 0.1% to 10% at, preferably about 1% at, of SiO₂.

By “hafnium oxides (HSO) doped with silicon” is meant in particular hafnium oxides comprising from 0.1 to 10% at, preferably about 1% at, of SiO₂.

“Ferroelectric multilayer device M” means in particular that the multilayer device, when considered as a whole, is ferroelectric. The device is therefore ferroelectric overall, even if this is not necessarily the case for all the layers of said device.

Surprisingly, it has also been shown that the multilayer device M is ferroelectric, despite the presence of layers that may be non-ferroelectric or even anti-ferroelectric.

And, just as surprisingly, the nature and the position of the layers A and B as defined above allows to obtain a definite and well-defined ferroelectric multilayer device.

Without wishing to restrict ourselves to any one theory, the layers A, particularly the first, are likely to facilitate the formation of a ferroelectric material. The layers A are stable, even at thicknesses of less than 10 nm.

Again without wishing to restrict ourselves to any one theory, the layer or layers B are likely to promote the transition from the tetragonal phase to the orthorhombic phase, thereby stabilizing the ferroelectric phase.

This is counter-intuitive as it could be considered that the layer or layers B crystallize more rapidly than the layers A, creating a tensile stress on the upper layer, and leading to a reduction in the activation energy to transform the tetragonal phase into a monoclinic phase. The monoclinic phases would have become dominant over the orthorhombic phase in the sample, allowing to form a final ferroelectric structure.

In addition, the layer or layers B may allow to reduce the annealing temperature of the structure, as they crystallize at lower temperatures. And beneficially, to obtain said final device M without going through the upper layer etching step (i.e. with annealing of the desired number of initial layers), it would be necessary to perform the annealing step at about 800° C., which is incompatible with the elements already present on the substrate. By producing a greater number of layers (stack M′), annealing may be carried out at a much lower temperature, for example around 400° C., which is perfectly compatible with the elements already present on the substrate.

Thus, the structure, the properties and the very nature of the layers of the multilayer device as obtained at the end of the method of the disclosure differ completely from that of a stack of layers (A/B), with n≥1, in particular by their crystallographic nature. And the same applies to the device after etching, in relation to a set of initial layers (A/B), arbitrarily reduced by the layers corresponding to those etched.

For the above reasons, the function (and therefore the interest) of selective etching as defined within the framework of the present disclosure is completely different from that of simple monolayer etching A/B.

“Ferroelectric” refers in particular to a device which has an electrical polarization in the spontaneous state, which may be reversed by the application of an external electric field, as measured for example by current response to the applied voltage.

By “a layer A (or B) being, independently, constituted by or comprising etc.”, we mean in particular that the layers A may be different from one another, while always being constituted by or comprising a compound selected from the group defined above.

According to a particular embodiment, the layers A (when there is more than one) and/or the layers B (when there is more than one) consist of or comprise the same compound as defined above.

Thus, the device M, after step (iii) and after step (vi), when step (vi) is carried out, corresponds to a device MFM (for “Metal Ferroelectric Metal”), the preparation of which consists of depositing a ferroelectric multilayer material, in particular by ALD, between two metal electrodes.

In a particular embodiment, n is from 2 to 25, in particular from 2 to 20, n being for example 2 or 3, in particular 3.

In a particular embodiment, n′ is from 3 to 26, in particular from 3 to 21, n′ being 5 for example.

In a particular embodiment, the last layer of the multilayer device M is a layer A.

The “last layer of the multilayer device M” refers in particular to the layer furthest from the substrate or the lower metal electrode.

In a particular embodiment, the substrate is a substrate made of or comprising silicon.

In a particular embodiment, the multilayer device M′ is prepared by successive deposition of layers A and B, in particular by an atomic layer deposition (ALD) technique.

The atomic layer deposition technique is likely to be able to develop conformal, homogeneous thin films while controlling their thickness with a sub-nanometer precision.

Typically, the ALD process begins by flooding the reaction chamber with a precursor that coats (or ‘adsorbs’) the exposed surface of the substrate. This process is referred to as self-limiting, as the precursor may only adsorb on exposed areas; once all these are covered, the adsorption stops. A second gas is then introduced and reacts with the precursor to form the desired material. This second step is also self-limiting: once the available precursor sites have been exhausted, the reaction stops. These two steps are repeated until the desired film thickness is achieved. The growth rate is generally quantified by growth per cycle (GPC). The typical ALD cycle consists of two half-cycles, sequential doses of precursor and co-reactant, which are separated by purge and pump steps, leading to self-limiting layer growth. The co-reactants and the oxidants are generally sources of oxygen (H₂Oor oxygen plasma). To obtain the multilayer material, different ALD monolayers are produced, alternating the pulses of precursors.

According to a particular embodiment, the precursors of the hafnium and zirconium oxides, when deposited by an atomic layer deposition technique, are halogenated precursors, in particular HfCl₄ and ZrCl₄ respectively.

In another particular embodiment, organometallic precursors such as TDMAZ (for Tetrakis-dimethylamino-zirconium-IV) may be used.

In another embodiment, the multilayer device M′ is prepared by successive deposition of the layers A and B using other techniques well known to the person skilled in the art, in particular a PVD (Physical Vapor Deposition), CVD (Chemical Vapor Deposition) or PLD (Pulsed Laser Deposition) deposition technique.

According to a particular embodiment, the layers A and/or B of the multilayer device M and/or of the multilayer device M′ have a thickness of between 0.5 and 5 nm, in particular of about 2 nm.

In a particular embodiment, the layers A have a thickness of between 0.5 nm and 5 nm, preferably about 2 nm, and the layers B have a thickness of between 0.5 nm and 5 nm, preferably about 2 nm.

In a particular embodiment, the multilayer device M and/or the multilayer device M′ have a thickness of less than 50 nm, in particular less than or equal to 15 nm, in particular less than or equal to 10 or 6 nm.

Removal of step (iv) may be carried out using prior art techniques such as inductively coupled plasma reactive ion etching (ICP-RIE), for example using a halogenated gas-based chemistry (Cl₂, BCl₃, CHF₃) in combination with other gases (Ar, N₂, O₂, He).

Other chemical removal techniques may be used, for example to remove the titanium nitride layer, such as the mixture formed by the chemical elements ammonia hydroxide (NH₄OH), hydrogen peroxide H₂O₂ and deionized water H₂O heated at 60° C.

The etching in step (v) allows to reduce the thickness of the total stack.

Without wishing to restrict ourselves to any theory, the etching of layers A and B in step (v) is selective because it exploits the difference in orientation/structure of said layers A and B. In contrast, this selectivity is not achieved in a standard, uniform and homogeneous ferroelectric material wherein the elements of layers A and B would be mixed.

Experimentally, and as is well known to the person skilled in the art, the thicknesses of the structures may be controlled as a function of the immersion or etching time and the chemical composition of the liquids used.

In a particular embodiment, the selective etching in step (v) is a total etching of the upper n′-n layers, opposite to the lower metal electrode.

In another particular embodiment, the selective etching in step (v) is partial (i.e. not complete). In this case, some or all of the top n′-n layers are only partially etched and remain on the device M.

According to a particular embodiment, the selective etching in step (v) is a wet or dry etching, in particular an etching (ALE), for example plasma etching (anisotropic), or thermal etching (isotropic).

In general, and as is well known to those skilled in the art, there are two main classes of etching method: the wet etching, where the material is dissolved when immersed in a chemical solution. And dry etching, where the material is sprayed or dissolved using reactive ions or a vapor-phase etchant. When said material is dissolved, and without wishing to restrict ourselves to any particular theory, it is typically the reaction of the material with ions or other substances that creates volatile species.

The speed at which the etching method occurs is referred to as the etching speed. The etching process is said to be isotropic if it proceeds in all directions at the same speed. If it takes place in a single direction and is strongly dependent on the crystalline structure of the material, then it is anisotropic. An important consideration in any etching process is the ‘selectivity’ of the etchant. The selectivity is achieved when two different materials have different etching speeds under the same conditions or when one material etch while the other do not etch. The selectivity is measured as the ratio between the different etching speeds of the etchant for different materials. The anisotropic etching is made possible by the distinct crystalline structures and orientations of the different materials making up the multilayer structure. The exposure to different etching speeds or chemical compositions is carried out according to the crystallinity of the material.

For example, in the case of an HfO₂ and ZrO₂ multilayer structure, a thermal atomic layer etching (ALE) may be carried out using fluorination and ligand exchange reactions. For example, HF may be used for fluorination and Sn(acac)₂, AlCl(CH₃)₂ [dimethylaluminium chloride (DMAC)] or TiCl₄ used as metal precursors for ligand exchange. The method referred to as Atomic layer etching (ALE) method is a method used to remove thin films with Angstrom-like precision using sequential and self-limiting surface reactions.

According to a particular embodiment, the disclosure relates to a method as described above, wherein:

The layer A of the device M′ is predominantly amorphous;

The layer A of the device M is predominantly orthorhombic;

The layer B of the device M′ is predominantly tetragonal;

The layer B of the device M is predominantly tetragonal.

“Predominantly amorphous, orthorhombic or tetragonal” means in particular that the layer is more than 50% amorphous, orthorhombic or tetragonal, respectively.

According to a particular embodiment, a part of the annealing step (iii) may be confused with step (ii). By way of example, the thermal budget of the method ALD (400° C. for 15 minutes) typically required to deposit a 10 nm TiN upper electrode layer may be sufficient for the crystallization of the last layer A or B, in particular A.

The annealing may be carried out using any technique well known to the skilled person, such as rapid thermal annealing (RTA), or annealing using an oven, hot plate, radiation-assisted annealing, or laser annealing.

According to a particular embodiment, the annealing in step (iii) is carried out at a temperature of 300 to 600° C., in particular 300 to 500° C., in particular around 400° C.

In a particular embodiment, step (vi) is carried out.

In a particular embodiment, step (vi) is not followed by an annealing step.

According to a particular embodiment, which the metal electrode mentioned in relation to step (ii) and/or the metal electrode mentioned in relation to step (vi) are deposited by physical vapor deposition (PVD) or chemical vapor deposition (CVD).

In a particular embodiment, the lower metal electrode mentioned in relation to step (i) is in contact, opposite to layer A, with a substrate.

In a particular embodiment, the substrate is a substrate made of or comprising silicon.

In a particular embodiment, the metal electrode mentioned in relation to step (i) is deposited by physical vapor deposition (PVD) or chemical vapor deposition (CVD).

According to a particular embodiment, the metal electrode mentioned in relation to step (i), the metal electrode mentioned in relation to step (ii) and/or the metal electrode mentioned in relation to step (vi) consist of or comprise a metal selected in particular from titanium, gold, platinum aluminum, ruthenium, molybdenum, copper and tungsten, a material comprising said metal, in particular a metal nitride, for example TiN, WN, TaN or MoN, or mixtures thereof.

According to a particular embodiment, the metal electrode mentioned in relation to step (i), the metal electrode mentioned in relation to step (ii) and/or the metal electrode mentioned in relation to step (vi) have a thickness of from 2 or 5 to 500 nm, in particular from 2, 5 or 10 to 100 nm, in particular from 2 or 5 to 20 nm.

The substrate, or when absent, the lower metal electrode, may be planar or non-planar. Since the assembly of the layers described above (the at least one layer A, the at least one layer B, and when present, the lower metal electrode and/or the upper metal electrode) generally has a constant thickness (typically a thickness being ±10%, in particular ±1%, of its mean value), the assembly of the layers described above has the same structural geometry as the substrate on which this assembly rests, or when absent, as the lower metal electrode on which it rests.

According to another aspect, the present disclosure also relates to a method for preparing three-dimensional structures comprising at least one device M as described above, in particular a plurality of devices M, which is prepared according to the steps as described above.

The device M according to the disclosure may be used in the preparation of ferroelectric MIM (Metal-Isolant-Metal) capacitors, in particular in a memory device.

### Definitions

As understood here, the value ranges in the form of “x-y” or “from x to y” or “between x and y” include the bounds x and y, the integers between these bounds, and all other real numbers between these bounds. For example, “1-5”, or “from 1 to 5” or “between 1 and 5” refer to the integers 1, 2, 3, 4 and 5, as well as all other real numbers between 1 and 5. Preferred embodiments comprise each individual integer in the value range, as well as any sub-combination of these integers and any set of real numbers between these integers. For example, the preferred values for “1-5” may comprise the integers 1, 2, 3, 4, 5, 1-2, 1-3, 1-4, 1-5, 2-3, 2-4, 2-5, etc.

As used in this description, the term “about” refers to a range of values within ±10% of a specific value. For example, the term “about 20” comprises the values of 20±10%, i.e., the values of 18 to 22.

By layer we mean in particular a stratum of superimposed elements. This stratum generally refers to a layer whose physico-chemical and structural properties are uniform and homogeneous, both in plan and in depth.

By first layer, we mean in particular a layer in contact with a second layer and, optionally, with a substrate.

By second layer, we mean in particular a layer in contact with the first layer and, where present, the third layer.

By third layer we mean, in particular, a layer in contact with the second layer and, where present, the fourth layer, and so on.

### Example 1: Preparation of a Device According to a Method of the Disclosure

### Step 1: Production of the Ferroelectric Stack

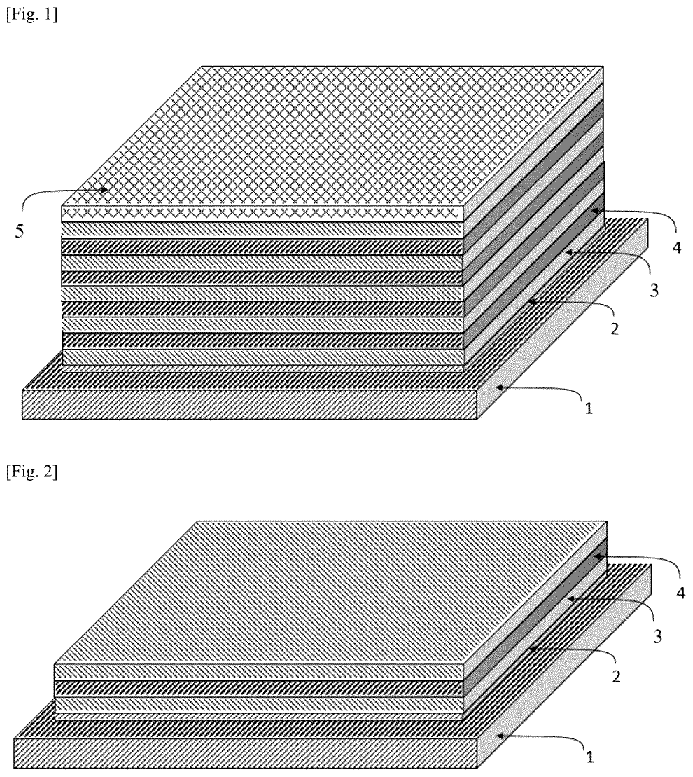

This step involves producing a stack of layers A and B on a generally silicon substrate (1) containing a metallic lower electrode (2) (FIG. 1). Generally speaking, the capacitance MFM (Metal Ferroelectric Metal) as such is achieved by techniques known in the prior art. FIG. 1 is a schematic representation of a top view of an elementary capacitor arranged on the rigid substrate. The configuration shown in FIG. 1 is given by way of example to illustrate the principles of this disclosure. The stack of an elementary capacitance shown in FIG. 1 consists of lower (2) and upper (5) electrodes of a metallic nature (for example titanium, gold, platinum aluminum, tungsten or any other metal used as a collector) arranged on the rigid substrate (1). The lower (2) and upper (5) electrodes are made of materials with a good electronic conductivity (e.g. TiN, TaN, W, etc.). This example uses titanium (TiN) electrodes with a thickness of 15 nm for the lower electrode (2) and 50 nm for the upper electrode (5), obtained by vacuum deposition (PVD for Physical Vapor Deposition) or CVD (Chemical Vapor Deposition). The ferroelectric dielectric multilayer structure is an electronic insulator. In this example, it is a 2 nm thick layer of HfO₂ (3) and 2 nm thick of ZrO₂ (4) but it may be replaced by other materials as defined above. Energy is required to initiate the chemical reactions between the injected precursor and the surface of the sample. It is supplied here in the form of thermal energy. The typical temperatures for these reactions are between 150° C. and 300° C. and depend on the type of precursor used. The ferroelectric thin films prepared by thermal ALD using chlorinated precursors are deposited at 300° C., for example. In one embodiment, a layer of HfO₂ (3) is formed on a lower electrode (2) mounted in a reaction chamber using ALD in a repetitive sequence comprising pulsing a hafnium-containing precursor into the reaction chamber followed by pulsing a purge gas and then pulsing a first oxygen-containing precursor into the chamber. Using ALD, a layer of HfO₂ is formed using HfCl₄ as the hafnium-containing precursor, water vapor as the first oxygen-containing precursor and argon as the purge and carrier gas. After forming the HfO₂ layer (3), the ZrO₂ layer (4) is formed on the HfO₂ layer (3). The ZrO₂ layer (4) is formed by ALD. In particular, a repeating sequence comprises the use of ZrCl₄ as the zirconium-containing precursor with a vapor solution of H₂O as the oxygen-containing precursor, and argon as the purge gas and carrier gas. The HfO₂/ZrO₂ nanolaminate comprises multiple layers of the HfO₂/ZrO₂ composite, the initial layer disposed on a lower electrode (2) being a layer of HfO₂. (3) After this initial layer of HfO₂ (3) are alternating layers of HfO₂ and ZrO₂, each with the desired layer thickness, applying the appropriate number of cycles according to the GPC of each material. And the termination layer being a layer of HfO₂ in this embodiment. After the ALD deposition method under these conditions, an amorphous material is generally obtained. The upper electrode (5) is deposited and, once the capacitance MFM has been fully integrated, the structure is subjected to thermal annealing at 400° C. for 1 hour in a nitrogen atmosphere, for example, to obtain a crystalline material with an orthorhombic phase and ferroelectric properties. However, each unit layer will have a different crystalline orientation, as shown in FIG. 1.

The term “nanolaminate” refers to a composite film of ultra-thin layers of two or more materials in a stack of layers, where the layers are alternating layers of composite film materials. Generally speaking, nanolaminates have thicknesses of the order of nanometers. Each individual layer of material in the nanolaminate may be as thin as a single layer of material. A nanolaminate of HfO₂ and ZrO₂ comprises at least a thin layer of HfO₂ and a thin layer of ZrO₂, and is generally written as a nanolaminate of HfO₂/ZrO₂.

### Step 2: Selective Etching of the Multilayer Structure

This step allows to reduce the final thickness of the ferroelectric multilayer structure after the capacitance MFM has been fully integrated. This operation is carried out by selective wet or dry etching of the material. The upper electrode layer, titanium nitride for example, is normally etched using a gas source comprising chlorine and a fluorocarbon. Once the upper electrode has been removed, the multilayer structure becomes accessible for a selective etching, due to the different phases and crystalline orientations of the materials obtained after annealing.

In accordance with one embodiment of the present disclosure, selective etching of the structure is carried out, using the respective etching speeds R1 and R2, for the layers composed of material A and material B, respectively. Etching rates may be appropriately selected on the basis of known factors, such as time, temperature, type of acid, fluoride and oxide to be etched, and selectivity obtained for the specific type of materials surrounding the oxide to be etched, and other known or easily determined factors. As indicated, the objective of the present disclosure is to etch oxides, for example hafnium or zirconium oxides as defined above, selectively with respect to materials which generally surround or exist in adjacent or nearby structures, and which could be etched by the same etching composition in the absence of such selectivity. Thus, the etching composition may have a high etching rate of these oxides, while having a relatively low etching rate of those materials that are not configured to be etched, such as nitrides, metals, silicon and photoresist materials (photosensitive resins).

By way of example, an HfO₂ selective wet etching composition comprising hydrofluoric acid (HF) may be proposed. As the crystalline HfO₂ is not etched in a dilute HF solution at room temperature, it is possible to perform the removal by controlling the etching rate as a function of temperature. An etching rate of around 500 nm/min is obtained in a 20% concentrated solution of HF by heating the solution to 80° C. In addition, the amorphous HfO₂ may be removed by HF in wet HF etching at room temperature. In addition, good properties of Cl₂-based and BCl₃-based plasmas for etching ZrO₂ and HfO₂ may be obtained. Generally speaking, the same behaviors were observed for HfO₂ and ZrO₂, but with a higher etching rate for ZrO₂, favoring a greater selectivity. In addition, the atomic layer etching (ALE) of HfO₂ and ZrO₂ may be achieved using sequential exposures with hydrogen fluoride (HF) as the fluorination reagent and dimethylaluminium chloride (DMAC, AlCl(CH₃)₂) as the metal reagent for ligand exchange. The DMAC could provide CH₃ or Cl ligands for the ligand exchange reaction. The presence of the Cl ligand on the DMAC led to an efficient etching of HfO₂ and ZrO₂ attributed to the formation of stable and volatile chloride species. The etching rates and the mass changes during the individual HF and DMAC reactions are distinct for the different HfO₂ and ZrO₂ layers and may be achieved by thermal ALE at different temperatures, leading to a selective etching of each layer. The etching rates of 0.98 Å/cycle and 1.33 Å/cycle for HfO₂ and ZrO₂, respectively, at 200, 225, 250, 275 and 300° C. may be used.

The etching operation of the layers may be repeated many times until the desired final thickness of the structure is reached, as shown in FIG. 2.

It should also be noted that the depth of the ablations and the quantity of layers etched may be obtained by varying the chemical attack time or the concentration of the reagents used, as well as the etching rate and the number of times the sequence is repeated.

### Step 3: Integration of the Device

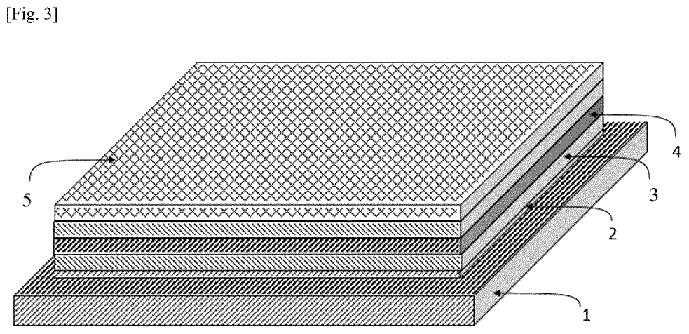

After selectively etching the multilayer structure and reducing the thickness of the ferroelectric dielectric layer, the final technical step involves integrating the upper electrode and ensuring that annealing is not required. FIG. 3 shows the stack formed by the substrate, the MFM capacitor with its lower (2) and upper (5) electrodes and its ultra-thin ferroelectric multilayer.

The upper metal electrode (5) is again deposited, titanium, gold, aluminum, platinum, tungsten, for example, obtained by PVD or CVD (chemical vapor deposition) deposition, and this time without subsequent annealing, while retaining the specificities of the BEOL technology and the ferroelectric dielectric properties of the material.

While illustrative embodiments have been illustrated and described, it will be appreciated that various changes can be made therein without departing from the spirit and scope of the invention.

1. A method for preparing a ferroelectric multilayer device M with n layers, n being between 2 and 100, device M comprising an alternation of at least one layer A and at least one layer B, said at least one layer A independently consisting of a compound selected from hafnium oxides (HfO₂), hafnium and zirconium oxides (HZO) enriched with hafnium, hafnium and zirconium oxides (HZO) doped with aluminum, hafnium and zirconium oxides (HZO) doped with lanthanum, hafnium and zirconium oxides (HZO) doped with gadolinium, hafnium and zirconium oxides (HZO) doped with yttrium, hafnium and zirconium oxides (HZO) doped with silicon, and hafnium oxides (HSO) doped with silicon,
said at least one layer B being, independently, constituted by a compound selected from zirconium oxides (ZrO₂), hafnium oxides (HZO) enriched with zirconium, and perovskites,
said method comprising the following steps:
(i) a step of preparing, on a lower metal electrode, a multilayer device M′ with n′ layers, n′ being between 3 and 101, with n′>n, with n′>n, comprising an alternation of said layers A and B, the first of the n′ layers, in contact with the lower metal electrode, being a layer A,
(ii) a step of depositing an upper metal electrode on said multilayer device M′ obtained at the end of step (i), opposite to said lower metal electrode,
(iii) a step of annealing the device obtained at the end of step (ii),
(iv) a step of removing the upper metal electrode from the device obtained at the end of step (iii),
(v) a selective etching of the n′-n upper layers, opposite to the lower metal electrode, in particular completely, to obtain the multilayer device M on said lower metal electrode,
(vi) optionally, a step of depositing an upper metal electrode on said multilayer device M′ obtained at the end of step (v), opposite to said lower metal electrode.

2. The method according to claim 1, wherein the last layer of the multilayer device M is a layer A.

3. The method according to claim 1, wherein the multilayer device M′ is prepared by successive deposition of layers A and B by an atomic layer deposition (ALD) technique, wherein the precursors of the hafnium and zirconium oxides are halogenated precursors, wherein said halogenated precursors are HfCl₄ and ZrCl₄.

4. The method according to claim 1, wherein the layers A and B of the multilayer devices M and of the multilayer device M′ have a thickness of between 0.5 and 5 nm.

5. The method according to claim 1, wherein the layers A have a thickness of between 0.5 nm and 5 nm, and the layers B have a thickness of between 0.5 nm and 5 nm.

6. The method according to claim 1, wherein the multilayer device M and the multilayer device M′ have a thickness of less than 50 nm.

7. The method according to any one of the preceding claims claim 1, wherein the selective etching of step (v) is a wet or dry etching, said wet or dry etch comprising an atomic layer etching (ALE).

8. The method according to claim 1, wherein:
the layer A of the device M′ is predominantly amorphous;
the layer A of the device M is predominantly orthorhombic;
the layer B of the device M′ is predominantly tetragonal;
the layer B of the device M is predominantly tetragonal.

9. The method according to claim 1, wherein the annealing in step (iii) is carried out at a temperature of 300 to 600° C.

10. The method according to claim 1, wherein the metal electrode mentioned in relation to step (ii) and the metal electrode mentioned in relation to step (vi) are deposited by physical vapor deposition (PVD) or chemical vapor deposition (CVD).

11. The method according to claim 1, wherein the metal electrode mentioned in relation to step (i), the metal electrode mentioned in relation to step (ii) and/or the metal electrode mentioned in relation to step (vi) consist of a metal, a material comprising said metal, or mixtures thereof.

12. The method according to claim 1, wherein the metal electrode mentioned in relation to step (i), the metal electrode mentioned in relation to step (ii) and the metal electrode mentioned in relation to step (vi) have a thickness of from 2 to 500 nm.

13. The method of claim 1, wherein n is between 2 and 25.

14. The method of claim 1, wherein n′ is between 3 and 26.

15. The method of claim 4, wherein the layers A and B have a thickness of about 2 nm.

16. The method of claim 6, wherein multilayer device M and M′ have a thickness of less than or equal to 15 nm.

17. The method of claim 7, wherein the ALE is plasma etching (anisotropic) or thermal etching (isotropic).

18. The method of claim 9, wherein the annealing of step (iii) is carried out at a temperature of about 400° C.

19. The method of claim 11, wherein the metal is selected from the group consisting of titanium, gold, platinum, aluminum, ruthenium, molybdenum, copper, and tungsten.

20. The method of claim 11, wherein the material comprising said metal is a metal nitride, said metal nitride selected from the group consisting of TiN, WN, TaN, and MoN.
